(19) United States
(12) Patent Application Publication
(10) Pub. No.: US 2026/0052856 A1
(43) Pub. Date: Feb. 19, 2026

(54) DISPLAY PANEL, DISPLAY APPARATUS, AND METHOD FOR MANUFACTURING DISPLAY PANEL

(71) Applicants: KunShan Go-Visionox Opto-Electronics Co., Ltd., Kunshan (CN); Hefei Visionox Technology Co., Ltd., Hefei (CN)

(72) Inventors: Zhen FU, Hefei (CN); Xu QIAN, Hefei (CN); Ying SHEN, Kunshan (CN); Shuangbing ZHANG, Hefei (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/313,761

(22) Filed: Aug. 28, 2025

(30) Foreign Application Priority Data
Jun. 28, 2024 (CN) 202410865901.0

(51) Int. Cl. H10K 59/126; H10K 59/122

(52) U.S. Cl. CPC H10K 59/126; H10K 59/122

(57) ABSTRACT

The present application provides a display panel, a manufacturing method thereof, and an electronic device. The display panel includes: a substrate; an isolation structure located on one side of the substrate, the isolation structure comprising spaced isolation openings, the isolation structure including a support portion and a shielding portion located on a side of the support portion away from the substrate, wherein an orthographic projection of the shielding portion on the substrate lies within an orthographic projection of the support portion on the substrate; a light-emitting device, at least a portion of which is located within the isolation openings, the light-emitting device comprising a first electrode, a light-emitting unit, and a second electrode sequentially stacked in a direction away from the substrate; and the second electrode being electrically connected to the isolation structure. In a display panel with an isolation structure, the shielding portion at the top of the isolation structure is shortened before forming the encapsulation material layer, thereby reducing the influence of the shielding portion on the vapor deposition airflow during the vapor deposition of the encapsulation material layer, thus ensuring the structural stability of subsequently formed encapsulation units and improving encapsulation effectiveness.

### CROSS-REFERENCE TO RELATED APPLICATION(S)

This application claims priority to Chinese Patent Application No. 202410865901.0, filed on Jun. 28, 2024, which is incorporated herein by reference in its entirety.

### TECHNICAL FIELD

The present application relates to the technical field of displays, and in particular to a display panel, a method for manufacturing a display panel, and an electronic device.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

However, the process performance of conventional OLED display products needs to be improved.

### SUMMARY

In order to overcome the disadvantage in the prior art mentioned above, an objective of the present application is to provide a display panel including:
a substrate;
at least one isolation structure located on one side of the substrate, the isolation structure enclosing isolation openings, and each of the at least one isolation structure including a support portion and a shielding portion located on a side of the support portion away from the substrate, an orthographic projection of the shielding portion on the substrate being located within an orthographic projection of the support portion on the substrate, and at least part of a side of the isolation structure close to the substrate being electrically conductive; and
light-emitting devices at least partially located within corresponding isolation openings, each of the light-emitting devices including a first electrode, a light-emitting unit and a second electrode which are stacked in a direction away from the substrate, and the second electrode being electrically connected to the isolation structure.

In some possible implementations, the orthographic projection of the shielding portion on the substrate is located within an orthographic projection of the side of the support portion away from the substrate on the substrate.

Preferably, the orthographic projection of the shielding portion on the substrate coincides with the orthographic projection of the side of the support portion away from the substrate on the substrate.

Preferably, a thickness of the shielding portion is less than a thickness of the support portion in the direction away from the substrate.

Preferably, the shielding portion and the support portion are made of different materials.

In some possible implementations, the display panel further includes encapsulation units each located on a side of each of the plurality of light-emitting devices away from the substrate, each encapsulation unit at least partially extending from an interior of a corresponding one of the isolation openings, along a side wall of the isolation structure facing the isolation opening, to a side of the isolation structure away from the substrate.

In some possible implementations, each encapsulation unit includes a first portion located within the isolation opening, a second portion located on the side wall of the isolation structure facing the isolation opening, and a third portion located on a side of the isolation structure away from the substrate, where the second portion connects the first portion and the third portion.

A gap is provided between the third portion and the side of the shielding portion away from the substrate.

Preferably, an average film thickness of the first portion is greater than or equal to an average film thickness of the second portion.

Preferably, an orthographic projection of the first portion on the substrate does not overlap with an orthographic projection of the third portion on the substrate.

In some possible implementations, the encapsulation units corresponding to at least part of adjacent light-emitting units are connected to each other on the side of the isolation structure away from the substrate.

Preferably, the encapsulation units corresponding to at least part of the light-emitting units that have a same emitting color and that are adjacent to each other are connected to each other on the side of the isolation structure away from the substrate.

In some possible implementations, each of the at least one isolation structure includes a connecting portion and a support portion located on a side of the connecting portion away from the substrate, where the connecting portion is electrically conductive; and the second electrode is electrically connected to the connecting portion.

Preferably, an orthographic projection of a side of the support portion close to the substrate on the substrate is located within an orthographic projection of the connecting portion on the substrate.

Preferably, the support portion is electrically conductive, and the second electrode is electrically connected to the support portion.

Preferably, an etching resistance of the connecting portion is greater than an etching resistance of the support portion.

Preferably, a material of the connecting portion includes metal, and/or a material of the support portion includes at least one of metal, an inorganic material, and an organic material.

In some possible implementations, the orthographic projection of the side of the support portion away from the substrate on the substrate is located within the orthographic projection of the side of the support portion close to the substrate on the substrate.

Preferably, a thickness of the connecting portion is less than a thickness of the support portion in the direction away from the substrate.

In some possible implementations, the orthographic projection of the side of the support portion close to the substrate on the substrate is located within the orthographic projection of the side of the support portion away from the substrate on the substrate; and a thickness of the connecting portion is less than a thickness of the support portion in the direction away from the substrate.

In some possible implementations, the orthographic projection of the side of the support portion close to the substrate on the substrate is located within the orthographic projection of the side of the support portion away from the substrate on the substrate;
an orthographic projection of the side of the connecting portion away from the substrate on the substrate is located within an orthographic projection of a side of the connecting portion close to the substrate on the substrate; and
preferably, a ratio of a thickness of the support portion to a thickness of the connecting portion ranges from 2:3 to 3:2 in the direction away from the substrate.

In some possible implementations, a side surface of the support portion facing the isolation opening includes a recess that is recessed in a direction away from the isolation opening.

Optionally, a thickness of the connecting portion is less than a thickness of the support portion in the direction away from the substrate.

In some possible implementations, the display panel further includes a second encapsulation layer and a third encapsulation layer which are located on a side of each of the encapsulation units away from the substrate and are stacked in the direction away from the substrate.

Preferably, a material of each of the encapsulation unit and the third encapsulation layer includes an inorganic material; and a material of the second encapsulation layer includes an organic material.

In some possible implementations, the display panel further includes a filter layer located on the side of the at least one isolation structure away from the substrate, where the filter layer includes a plurality of filter units, an orthographic projection of each of the filter units on the substrate at least partially overlapping with an orthographic projection of the light-emitting device on the substrate, and each of the filter units having a same transmitting color as an emitting color of a corresponding one of the light-emitting devices.

Preferably, the filter layer further includes light shielding units located between adjacent filter units, an orthographic projection of each of the light shielding units on the substrate at least partially overlapping with an orthographic projection of the isolation structure on the substrate.

In some possible implementations, a gap is provided between adjacent isolation structures, and the display panel further includes first touch traces disposed in the same layer as the isolation structures and each located in a gap between adjacent isolation structures;
or the display panel further includes a touch functional layer located on the side of the isolation structure away from the substrate, the touch functional layer including a plurality of second touch traces, an orthographic projection of each of the second touch traces on the substrate at least partially overlapping with an orthographic projection of the isolation structure on the substrate.

In some possible implementations, each of the at least one isolation structure further includes a light-transmitting opening located between adjacent isolation openings.

Preferably, the display panel includes a first active area and a second active area at least partially surrounding the first active area, and the light-transmitting openings are located in the first active area.

Preferably, the display panel further includes a plurality of array functional layers located between the substrate and the at least one isolation structure. Each array functional layer includes a light-transmitting region, an orthographic projection of the light-transmitting region on the substrate at least partially overlapping with an orthographic projection of the light-transmitting opening on the substrate.

In some possible implementations, each of the light-emitting units includes at least two light-emitting functional layers which are stacked in the direction away from the substrate and which have a same emitting color, and the light-emitting unit further includes a charge generation layer located between adjacent light-emitting functional layers.

Preferably, the light-emitting functional layer includes a hole transport layer, a light-emitting material layer, a hole blocking layer and an electron transport layer which are stacked in the direction away from the substrate.

Preferably, the light-emitting unit further includes a hole injection layer located between the light-emitting functional layer closest to the substrate and the first electrode, and/or an electron injection layer located between the light-emitting functional layer farthest from the substrate and the second electrode.

Preferably, the charge generation layer includes a first charge generation layer and a second charge generation layer which are stacked in the direction away from the substrate, the first charge generation layer including an N-type dopant material, and the second charge generation layer including a P-type dopant material.

A further objective of the present application is to provide a display panel including:
a substrate;
at least one isolation structure located on one side of the substrate, where the at least one isolation structure enclosing isolation openings; at least part of a side of the isolation structure close to the substrate being electrically conductive, and
the isolation structure includes a support portion and a shielding portion located on a side of the support portion away from the substrate;
light-emitting devices at least partially located within corresponding isolation openings; and
encapsulation units each located on a side of each of the plurality of light-emitting devices away from the substrate, each of the encapsulation units including a first portion located within the isolation opening, a second portion located on the side wall of the isolation structure facing the isolation opening, and a third portion located on a side of the isolation structure away from the substrate, where the second portion connects the first portion and the third portion; the second portion forms a continuous slope relative to the substrate, and a gap is provided between the third portion and the side of the shielding portion away from the substrate; and
an orthographic projection of a top portion of the second portion on the substrate is located on a side, away from the isolation opening, of an orthographic projection of a bottom portion of the second portion on the substrate.

A further objective of the present application is to provide a method for manufacturing a display panel, the method including:
providing a substrate;
forming at least one isolation structure on one side of the substrate, where the isolation structure encloses isolation openings, and the isolation structure includes a support portion and a shielding portion located on a side of the support portion away from the substrate, an orthographic projection of the support portion on the substrate being located within an orthographic projection of the shielding portion on the substrate; and the isolation openings include a first isolation opening and a second isolation opening;
sequentially providing a first light-emitting material layer and a first conductive material layer which are disposed in a full-coverage manner on a side of the isolation structure away from the substrate;
removing a portion of a part of the shielding portion close to the first isolation opening, so that an orthographic projection of the part of the shielding portion close to the first isolation opening on the substrate is located within an orthographic projection of the support portion on the substrate;
providing a first encapsulation material layer which is disposed in a full-coverage manner on a side of the first conductive material layer away from the substrate; and
etching the first encapsulation material layer, the first conductive material layer and the first light-emitting material layer to form an encapsulation unit, a second electrode and a light-emitting unit which are at least partially located in the first isolation opening.

In some possible implementations, after the step of etching the first encapsulation material layer, the first conductive material layer and the first light-emitting material layer, the method further includes:
sequentially providing a second light-emitting material layer and a second conductive material layer which are disposed in a full-coverage manner on a side of the isolation structure away from the substrate;
removing a portion of a part of the shielding portion close to the second isolation opening, so that an orthographic projection of the part of the shielding portion close to the second isolation opening on the substrate is located within an orthographic projection of the support portion on the substrate;
providing a second encapsulation material layer which is disposed in a full-coverage manner on a side of the second conductive material layer away from the substrate; and
etching the second encapsulation material layer, the second conductive material layer and the second light-emitting material layer to form an encapsulation unit, a second electrode and a light-emitting unit which are at least partially located in the second isolation opening.

In some possible implementations, the step of removing a portion of a part of the shielding portion close to the first isolation opening includes:
removing a portion of a part of the shielding portion close to the first isolation opening by means of laser etching.

The present application further provides an electronic device including a display panel provided in the present application, or a display panel manufactured by the method for manufacturing a display panel provided in the present application.

The present application has the following beneficial effects with respect to the prior art.

According to a display panel, a method for manufacturing a display panel, and an electronic device provided in the present application, in a display panel having isolation structures, the shielding portion at the top end of each isolation structure is shortened before providing the encapsulation material layer, which can thus reduce the impact of the shielding portion on evaporation gas flow during formation of the encapsulation material layer by evaporation, so as to ensure the structural stability of the subsequently formed encapsulation units, thereby improving the encapsulation effectiveness.

### BRIEF DESCRIPTION OF THE DRAWINGS

In order to illustrate the technical solutions of embodiments of the present application more clearly, the drawings required in the embodiments will be briefly introduced below. It should be understood that the following drawings only show some embodiments of the present application, and therefore should not be construed as a limitation on the scope. For those of ordinary skill in the art, other related drawings can be obtained from these drawings without involving any inventive effort.

FIG. 1 is a schematic diagram of an existing display panel;

FIG. 2 is a schematic flowchart of steps of a method for manufacturing a display panel according to an embodiment of the present application;

FIG. 3 is a first schematic diagram of a display panel according to an embodiment of the present application;

FIG. 4 is a second schematic diagram of a display panel according to an embodiment of the present application;

FIG. 5 is a third schematic diagram of a display panel according to an embodiment of the present application;

FIG. 6 is a fourth schematic diagram of a display panel according to an embodiment of the present application;

FIG. 7 is a fifth schematic diagram of a display panel according to an embodiment of the present application;

FIG. 8 is a sixth schematic diagram of a display panel according to an embodiment of the present application;

FIG. 9 is a seventh schematic diagram of a display panel according to an embodiment of the present application;

FIG. 10 is an eighth schematic diagram of a display panel according to an embodiment of the present application;

FIG. 11 is a twelfth schematic diagram of a display panel according to an embodiment of the present application;

FIG. 12 is a thirteenth schematic diagram of a display panel according to an embodiment of the present application;

FIG. 13 is a fourteenth schematic diagram of a display panel according to an embodiment of the present application;

FIG. 14 is a fifteenth schematic diagram of a display panel according to an embodiment of the present application;

FIG. 15 is a sixteenth schematic diagram of a display panel according to an embodiment of the present application;

FIG. 16 is a schematic diagram showing regions of a display panel according to an embodiment of the present application; and

FIG. 17 is a schematic diagram of a light-emitting unit according to an embodiment of the present application.

List of reference signs: 111—Substrate; 112—Array functional layer; 113—Connection trace; 120—First electrode; 130—Pixel defining layer; 140—Isolation structure; 141—Support portion; 142—Shielding portion; 143—Receiving portion; 150—Light-emitting unit; 160—Second electrode; 170—Encapsulation unit; 171—First portion; 172—Second portion; 1721—Slope; 173—Third portion; 180—Second encapsulation layer; 190—Third encapsulation layer; 1501—First light-emitting material layer; 1601—First conductive material layer; 1701—First encapsulation material layer; 210—Filter unit; 220—Light shielding unit; 710—Light-transmitting opening; 810—First touch trace; 820—Second touch trace; 900—Cavity; AA1—First active area; AA2—Second active area; 151—Light-emitting functional layer; 1511—Hole transport layer; 1512—Electroluminescent layer; 1513—Hole blocking layer; 1514—Electron transport layer; 152—Charge generation layer; 1521—First charge generation layer; 1522—Second charge generation layer; 153—Hole injection layer; 154—Electron injection layer.

### DETAILED DESCRIPTION OF THE EMBODIMENTS

In order to make the objectives, technical solutions and advantages of embodiments of the present application clearer, the technical solutions in the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application. Based on the embodiments of the present application, all other embodiments obtained by those of ordinary skill in the art without involving any inventive effort shall fall within the scope of protection of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center,” “upper,” “lower”, “vertical”, “horizontal”, “inner”, and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

In some solutions in which isolation structures are used in a display panel to disconnect the organic light-emitting functional layers of adjacent sub-pixels during an evaporation process, light-emitting units that have different emitting colors can be formed in different pixel openings by means of etching after full-layer evaporation. Reference can be made to relevant technical solutions of the isolation structure recited in patent applications PCT/CN2023/134518, 202310759370.2, 202310740412.8, 202310707209.0, and 202311346196.5, the contents of which are incorporated herein by reference.

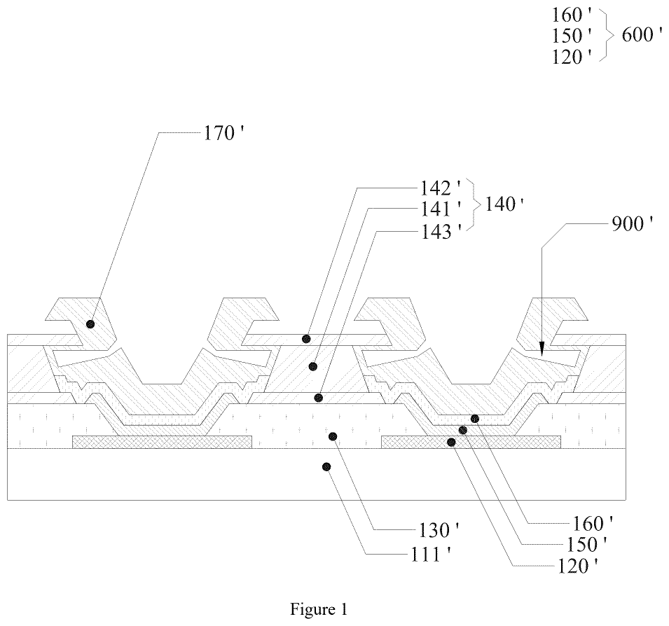

Referring to FIG. 1, such a display panel typically includes a substrate 111′, a pixel defining layer 130′ located on one side of the substrate 111′, isolation structures 140′ located on a side of the pixel defining layer 130′ away from the substrate 111′, light-emitting devices 600′ at least partially located in corresponding isolation openings formed by the isolation structures 140′, and encapsulation units 170′ each located on a side of the corresponding light-emitting device 600′ away from the substrate 111′.

Each isolation structure 140′ typically includes at least a support portion 141′ and a top portion located on a side of the support portion 141′ away from the substrate 111′, and some display panels include connecting portions 143′ each located on a side of the corresponding support portion 141′ close to the substrate 111′. An orthographic projection of the support portion 141′ on the substrate 111′ is located within an orthographic projection of the shielding portion 142′ on the substrate 111′, that is, the support portion 141′ is inwardly retracted relative to the shielding portion 142′ to form an undercut structure.

However, the inventors have found that during a manufacturing process for a display panel described above, when an encapsulation material for forming the encapsulation units 170′ is evaporated, the encapsulation material will accumulate at the undercut structure and quickly narrow to form a cavity 900′, making it difficult for the evaporation gas flow to subsequently enter the cavity 900′, and resulting in smaller thicknesses of the encapsulation units 170′ at corresponding positions in the cavity 900′, which reduces the structural stability of the encapsulation units 170′, and easily causes damage to the encapsulation units 170′ during the subsequent manufacturing process, leading to encapsulation failure problems.

In view of this, a solution of a display panel using isolation structures that can improve the structural stability of encapsulation units is provided according to an embodiment of the present application. This solution according to an embodiment of the present application is described in detail below.

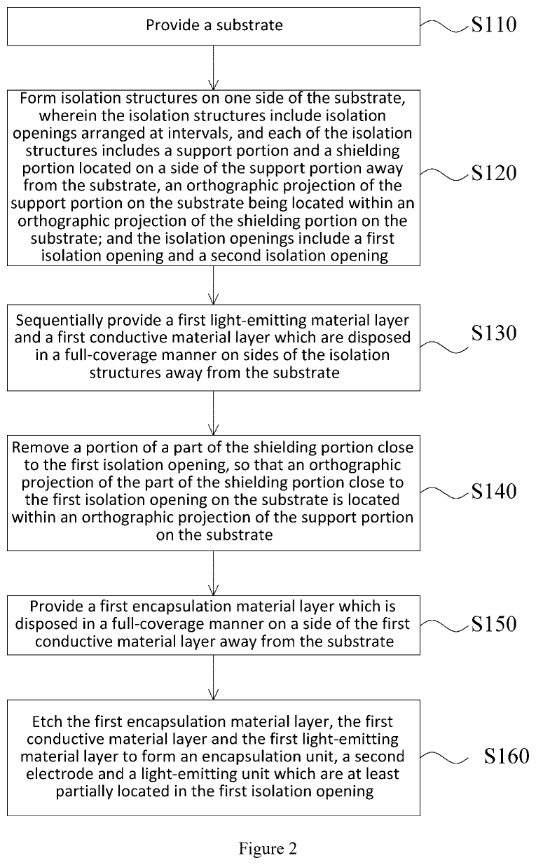

Referring to FIG. 2, FIG. 2 is a schematic flowchart of steps of a method for manufacturing a display panel according to an embodiment of the present application. The method may include the following steps.

At step S110, a substrate 111 is provided.

According to an embodiment of the present application, a material of the substrate 111 may include a flexible material. For example, the material of the substrate 111 may include polyimide (Pi). Alternatively, the material of the substrate 111 may include a rigid material. For example, the material of the substrate 111 may include glass.

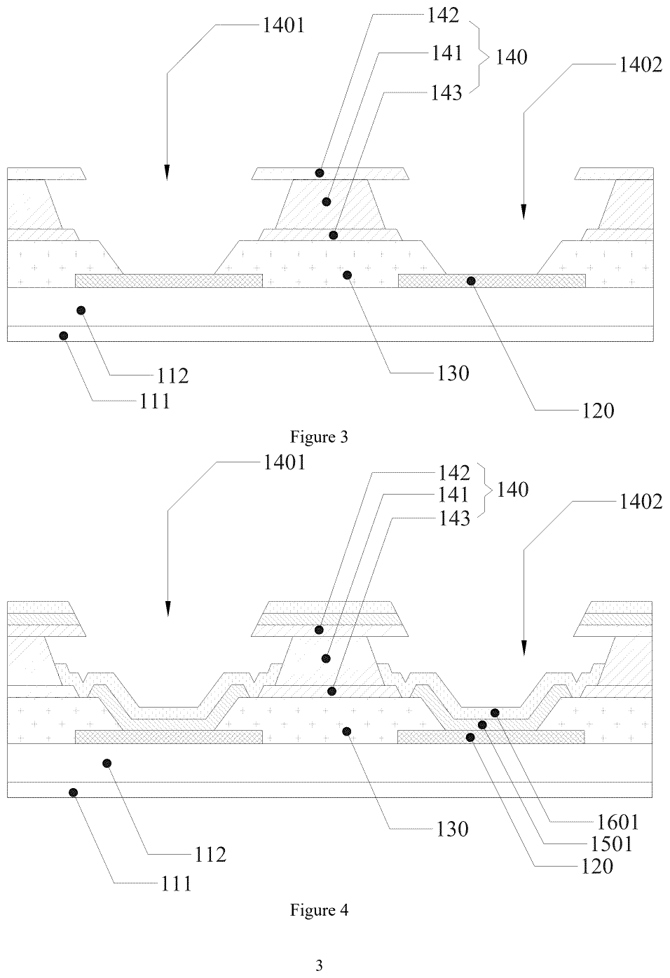

At step S120, isolation structures 140 are formed on one side of the substrate 111. The isolation structures 140 enclose isolation openings including a first isolation opening 1401 and a second isolation opening 1402. Each isolation structure 140 includes a support portion 141 and a shielding portion 142 located on a side of the support portion 141 away from the substrate 111, and an orthographic projection of the support portion 141 on the substrate 111 is located within an orthographic projection of the shielding portion 142 on the substrate 111. According to an embodiment of the present application, referring to FIG. 3, the support portion 141 of the isolation structure 140 is inwardly retracted relative to the shielding portion 142 to form an undercut structure.

Optionally, the isolation structure 140 may further include a connecting portion 143 located on a side of the support portion 141 close to the substrate 111, and the orthographic projection of the support portion 141 on the substrate 111 may be located within an orthographic projection of the connecting portion 143 on the substrate 111.

Optionally, an etching resistance of the support portion 141 may be weaker than an etching resistance of the shielding portion 142. In this way, the support portion 141 may be laterally etched, so that the support portion 141 of the isolation structure 140 is inwardly retracted relative to the shielding portion 142 to form the undercut structure.

In some possible implementations, first electrodes 120 may be first formed on one side of the substrate 111, a pixel defining layer 130 and an isolation structure layer are then sequentially formed on a side of the first electrodes 120 away from the substrate 111, and the isolation structure layer and the pixel defining layer 130 are then sequentially etched to form isolation openings and pixel openings for exposing the first electrodes 120. An orthographic projection of each pixel opening on the substrate 111 is located within an orthographic projection of the corresponding isolation opening on the substrate 111.

At step S130, a first light-emitting material layer 1501 and a first conductive material layer 1601 are sequentially provided in a full-coverage manner on sides of the isolation structures 140 away from the substrate 111.

Referring to FIG. 4, at step S130, full-layer evaporation may be performed on the side of the isolation structures 140 away from the substrate 111 to sequentially form the first light-emitting material layer 1501 and the first conductive material layer 1601. Since the support portion 141 in the isolation structure 140 is inwardly retracted relative to the shielding portion 142 to form the undercut structure, parts of the first light-emitting material layer 1501 and the first conductive material layer 1601 located in the isolation opening are disconnected from parts of the first light-emitting material layer 1501 and the first conductive material layer 1601 located on the shielding portion 142.

At step S140, a portion of a part of the shielding portion 142 close to the first isolation opening 141 is removed, so that an orthographic projection of the part of the shielding portion 142 close to the first isolation opening 141 on the substrate 111 is located within the orthographic projection of the support portion 141 on the substrate 111.

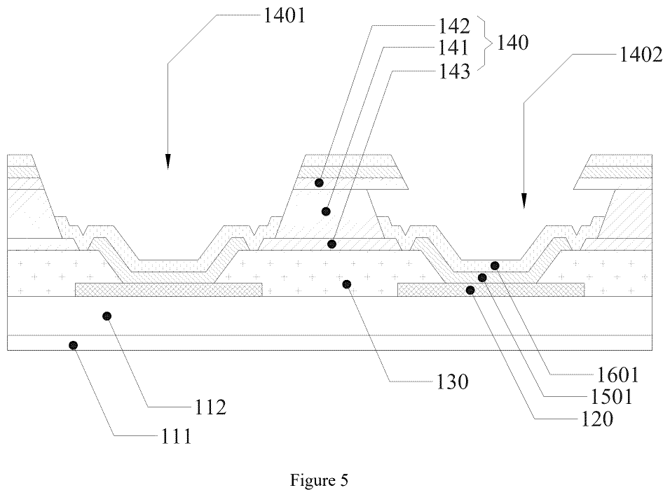

Referring to FIG. 5, at step S140, a portion of the part of the shielding portion 142 close to the first isolation opening 141 may be removed, so that the part of the shielding portion 142 close to the first isolation opening 141 is shortened in a direction parallel to the substrate 111, that is, a portion of the part of the shielding portion 142 close to the first isolation opening 141 that protrudes relative to the support portion 141 is shortened to be flush with a side surface of the support portion 141, thereby eliminating the undercut structure formed by the part of the shielding portion 142 close to the first isolation opening 141.

In addition, when the shielding portion 142 is shortened, the first light-emitting material layer 1501 and the first conductive material layer 1601 located on the side of the part of the shielding portion 142 away from the substrate 111 are also removed.

It should be noted that, at step S140, only the part of the shielding portion 142 close to the first isolation opening 1401 may be shortened, while the part of the shielding portion 142 close to the second isolation opening 1402 may not be processed.

In some possible implementations, the portion of the part of the shielding portion 142 close to the first isolation opening 1401 may be removed by laser etching.

At step S150, a first encapsulation material layer 1701 is provided in a full-coverage manner on the side of the first conductive material layer 1601 away from the substrate 111.

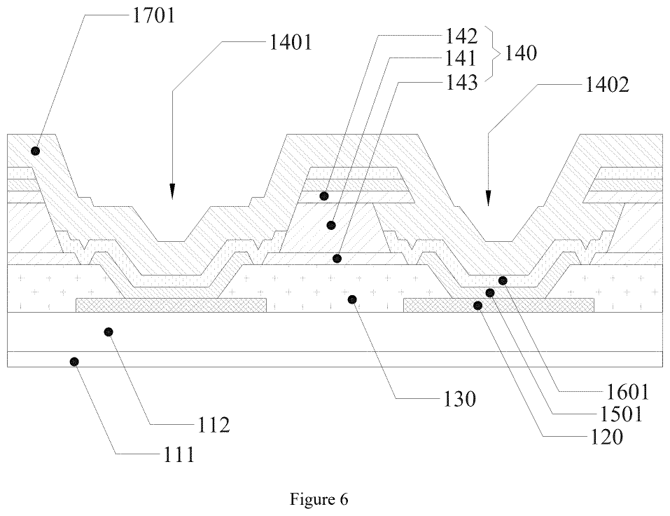

Referring to FIG. 6, at step S150, full-layer evaporation may be performed on the side of the first conductive material layer 1601 away from the substrate 111 to form a full-coverage first encapsulation material layer 1701.

During this process, since the part of the shielding portion 142 close to the first isolation opening 1401 is shortened at step S140, the undercut structure formed by the part of the shielding portion 142 close to the first isolation opening 1401 is eliminated, which reduces the obstruction of the shielding portion 142 to the evaporation gas flow during formation of the first encapsulation material layer 1701 by evaporation, thereby improving the uniformity in thickness of the first encapsulation material layer 1701 at different positions.

At step S160, the first encapsulation material layer 1701, the first conductive material layer 1601 and the first light-emitting material layer 1501 are etched to form an encapsulation unit 170, a second electrode 160 and a light-emitting unit 150 which are at least partially located in the first isolation opening 1401.

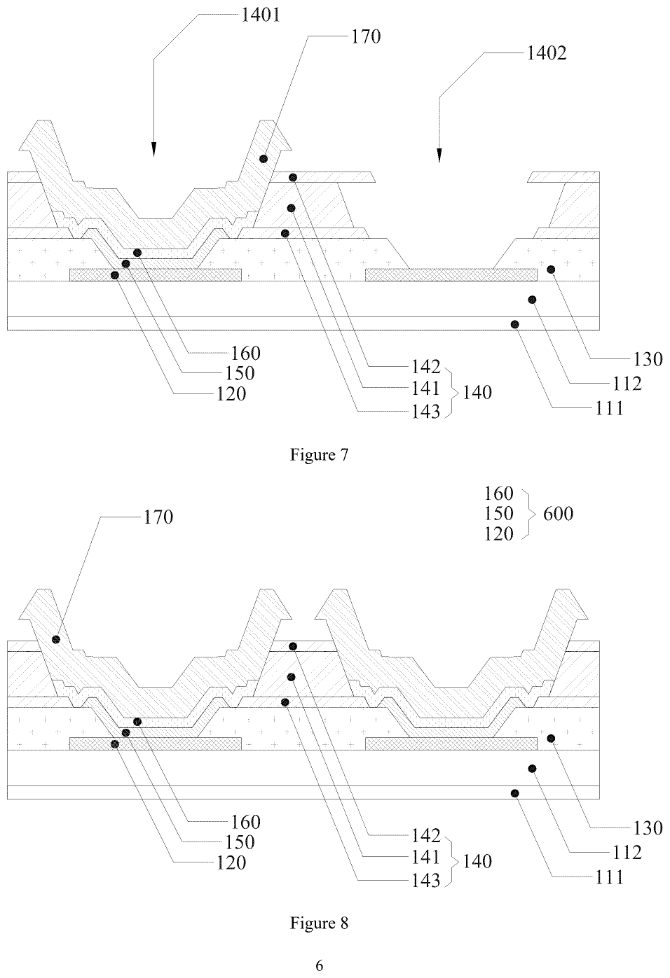

Referring to FIG. 7, at step S160, after providing an etch stop material to cooperate with a mask, the first encapsulation material layer 1701, the first conductive material layer 1601 and the first light-emitting material layer 1501 may be patterned by etching, so that parts of the first encapsulation material layer 1701, the first conductive material layer 1601 and the first light-emitting material layer 1501 located in the first isolation opening 1401 and/or close to the first isolation opening 1401 are retained, while the first encapsulation material layer 1701, the first conductive material layer 1601 and the first light-emitting material layer 1501 in other isolation openings are removed, thereby forming a light-emitting unit 150, a second electrode 160 and an encapsulation unit 170 which are at least partially located in the first isolation opening 1401.

For example, the etch stop material is first provided at the position of the first isolation opening 1401, and the other isolation openings (e.g., the second isolation opening 1402) except the first isolation opening 1401 are exposed.

The first encapsulation material layer 1701, the first conductive material layer 1601 and the first light-emitting material layer 1501 are then patterned by etching, so as to remove the parts of the first encapsulation material layer 1701, the first conductive material layer 1601 and the first light-emitting material layer 1501 in the second isolation opening 1402 while retaining the parts of the first encapsulation material layer 1701, the first conductive material layer 1601 and the first light-emitting material layer 1501 in the first isolation opening 1401, thereby forming a light-emitting unit 150, a second electrode 160 and an encapsulation unit 170 which are at least partially located in the first isolation opening 1401.

In some possible implementations, the light-emitting unit 150, the second electrode 160 and the encapsulation unit 170 may be formed in other isolation openings subsequently by the same or similar steps.

For example, after forming the light-emitting unit 150, the second electrode 160 and the encapsulation unit 170 which are at least partially located within the first isolation opening 1401, the method according to an embodiment of the present application may further include the following steps.

At step S210, a second light-emitting material layer and a second conductive material layer are sequentially provided in a full-coverage manner on a side of the isolation structure 140 away from the substrate 111.

Since only the undercut structure of the isolation structure 140 at the first isolation opening 1401 is eliminated at step S140 with the undercut structure of the isolation structure 140 at the second isolation opening 1402 being retained, during evaporation of the second light-emitting material layer and the second conductive material layer at step S210, the undercut structure of the isolation structure 140 at the second isolation opening 1402 may disconnect the parts of the second light-emitting material layer and the second conductive material layer located within the second isolation opening 1402 and the parts of the second light-emitting material layer and the second conductive material layer located on the side of the isolation structure 140 away from the substrate 111.

At step S220, a portion of the part of the shielding portion 142 close to the second isolation opening 1402 is removed, so that an orthographic projection of the part of the shielding portion 142 close to the second isolation opening 1402 on the substrate 111 is located within the orthographic projection of the support portion 141 on the substrate 111.

At step S230, a second encapsulation material layer is provided in a full-coverage manner on the side of the second conductive material layer away from the substrate.

At step S240, the second encapsulation material layer, the second conductive material layer and the second light-emitting material layer are etched to form an encapsulation unit 170, a second electrode 160 and a light-emitting unit 150 which are at least partially located in the second isolation opening 1402.

Based on the above design, according to an embodiment of the present application, a part of the shielding portion 142 at a top end of the isolation structure 140 is shortened before providing the encapsulation material layer, which can thus reduce the impact of the shielding portion 142 on the evaporation gas flow during formation of the encapsulation material layer by evaporation, so as to ensure the structural stability of the subsequently formed encapsulation units 170, thereby improving the encapsulation effectiveness.

Referring to FIG. 8, FIG. 8 is a schematic diagram of a display panel according to an embodiment of the present application. The display panel may be manufactured by the method for manufacturing a display panel according to an embodiment of the present application. The display panel may include a substrate 111, isolation structures 140, and light-emitting devices 600.

According to an embodiment of the present application, a material of the substrate 111 may include a flexible material. For example, the material of the substrate 111 may include polyimide (Pi). Alternatively, the material of the substrate 111 may include a rigid material. For example, the material of the substrate 111 may include glass.

Optionally, according to an embodiment of the present application, a plurality of array functional layers 112, such as a buffer layer, an active layer, a plurality of metal layers, a plurality of insulating layers and a planarization layer, may be provided on one side of the substrate 111. The plurality of array functional layers 112 may have a structure such that a plurality of thin film transistors (TFTs) are formed at different positions and cooperate with each other to form a plurality of pixel drive units or drive circuits.

The isolation structures 140 are located on one side of the substrate 111. The isolation structures 140 enclose isolation openings. Each isolation structure 140 includes a support portion 141 and a shielding portion 142. An orthographic projection of the shielding portion 142 on the substrate 111 is located within an orthographic projection of the support portion 141 on the substrate 111. At least part of the isolation structure 140, for example, at least a part of the isolation structure 140 close to the substrate 111, is electrically conductive. In the display panel according to an embodiment of the present application, the shielding portion 142 in the isolation structure 140 is shortened, which eliminates the undercut structure formed by the shielding portion 142, thereby reducing the impact of the shielding portion 142 on the evaporation gas flow.

Optionally, the display panel according to an embodiment of the present application may further include a pixel defining layer 130 located between the isolation structures 140 and the substrate 111. The pixel defining layer 130 may include pixel openings arranged at intervals, and an orthographic projection of each pixel opening on the substrate 111 is located within the orthographic projection of the corresponding isolation opening on the substrate 111.

Each light-emitting device 600 is at least partially located in the corresponding isolation opening. The light-emitting device 600 includes a first electrode 120, a light-emitting unit 150 and a second electrode 160 which are stacked in a direction away from the substrate 111, the second electrode 160 being electrically connected to the isolation structure 140.

Based on the above design, in a display panel having isolation structures 140, a part of the shielding portion 142 at a top end of the isolation structure 140 is shortened before providing the encapsulation material layer, which can thus reduce the impact of the shielding portion 142 on the evaporation gas flow during formation of the encapsulation material layer by evaporation, so as to ensure the structural stability of the subsequently formed encapsulation units 170, thereby improving the encapsulation effectiveness.

In some possible implementations, the orthographic projection of the shielding portion 142 on the substrate 111 is located within the orthographic projection of the part of the support portion 141 away from the substrate 111 on the substrate 1111. That is, the shielding portion 142 is shortened to not exceed a surface of the support portion 141 away from the substrate 111. For example, the orthographic projection of the shielding portion 142 on the substrate 111 may coincide with the orthographic projection of the side of the support portion 141 away from the substrate 111 on the substrate 1111.

In this way, after the shielding portion 142 is shortened, sides of the shielding portion 142 and the support portion 141 facing the isolation opening are flush with each other, which reduces the impact on the evaporation gas flow during evaporation of the encapsulation material layer, making the encapsulation material layer formed by evaporation more uniform in thickness.

Optionally, in some possible implementations, a thickness of the shielding portion 142 is less than a thickness of the support portion 141 in the direction away from the substrate 111.

Optionally, the shielding portion 142 and the support portion 141 are made of different materials. For example, an etching resistance of the material of the support portion 141 may be weaker than an etching resistance of the material of the shielding portion 142.

In some possible implementations, the display panel further includes encapsulation units 170 each located on a side of the corresponding light-emitting device 600 away from the substrate 111, and each encapsulation unit 170 at least partially extends from an interior of a corresponding one of the isolation openings, along a side wall of the isolation structure 140 facing the isolation opening, to a side of the isolation structure 140 away from the substrate 111.

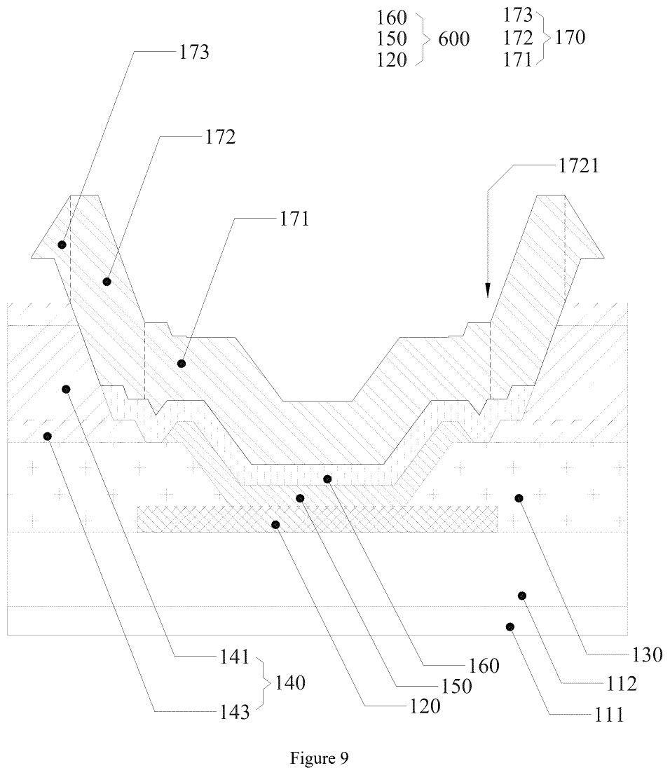

Specifically, in some possible implementations, referring to FIG. 9, each encapsulation unit 170 includes a first portion 171 located within the isolation opening, a second portion 172 located on the side wall of the isolation structure 140 facing the isolation opening, and a third portion 173 located on a side of the isolation structure 140 away from the substrate 111. The second portion 172 connects the first portion 171 and the third portion 173. A gap is provided between the third portion 173 and the side of the shielding portion 141 away from the substrate.

In some possible implementations, due to the different stacking directions of the evaporation materials during formation of the first portion 171 and the second portion 172 by evaporation, the first portion 171 and the second portion 172 may have a certain thickness difference, for example, an average film thickness of the first portion 171 is greater than or equal to an average film thickness of the second portion 172.

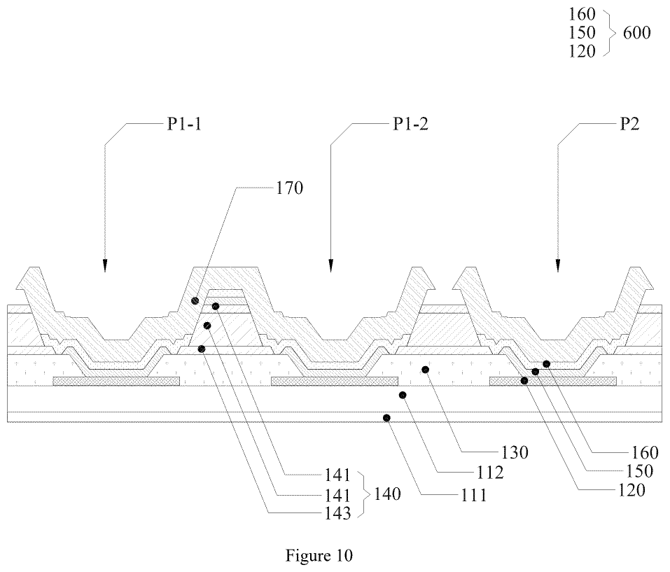

In some possible implementations, referring to FIG. 10, the encapsulation units 170 corresponding to at least part of adjacent light-emitting units 150 are connected to each other on the side of the isolation structure 140 away from the substrate 111.

Optionally, the encapsulation units 170 corresponding to at least part of the light-emitting units 150 that have a same emitting color and that are adjacent to each other are connected to each other on the side of the isolation structure 140 away from the substrate 111.

For example, in a scenario shown in FIG. 10, a sub-pixel P1-1 and a sub-pixel P1-2 are two sub-pixels that have a same emitting color and that are adjacent to each other, and the light-emitting units 150, the second electrodes 160 and the encapsulation units 170 corresponding to the sub-pixel P1-1 and the sub-pixel P1-2 may be formed in one etching step.

Specifically, during formation of the light-emitting units 150, the second electrodes 160 and the encapsulation units 170 corresponding to the sub-pixel P1-1 and the sub-pixel P1-2 by etching, the isolation openings corresponding to the sub-pixel P1-1 and the sub-pixel P1-2 may be covered by a continuous etch stop material, so that after etching, the encapsulation units 170 corresponding to the sub-pixel P1-1 and the sub-pixel P1-2 are connected to each other on the side of the isolation structure 140 away from the substrate 111.

In this case, the unetched parts of the light-emitting material layer and the conductive material layer may remain on the side of the isolation structure 140 between the sub-pixel P1-1 and the sub-pixel P1-2 away from the substrate 111.

The sub-pixel P1-2 and the sub-pixel P2 have different emitting colors, and their light-emitting units 150, second electrodes 160 and encapsulation units 170 are formed in different etching processes. Therefore, a certain gap is provided between the encapsulation units 170 corresponding to the sub-pixel P1-2 and the sub-pixel P2.

In some possible implementations, each isolation structure 140 includes a connecting portion 143 and a support portion 141 located on a side of the connecting portion 143 away from the substrate 111. The connecting portion 143 is electrically conductive, and the second electrode 160 is electrically connected to the connecting portion 143. In this way, the effectiveness of electrical connection between the second electrode 160 and the isolation structure 140 can be ensured.

Optionally, an orthographic projection of the side of the support portion 141 close to the substrate 111 on the substrate 111 is located within an orthographic projection of the connecting portion 143 on the substrate 111. That is, according to an embodiment of the present application, a part of the connecting portion 143 is exposed relative to the support portion 141, so that the second electrode 160 formed by evaporation may overlap the connecting portion 143, which increases the contact area between the second electrode 160 and the connecting portion 143, thereby improving the effectiveness of electrical connection.

Further, in some possible implementations, the support portion 141 is also electrically conductive, and the second electrode 160 may be electrically connected to the support portion 141. For example, the connecting portion 143 and the support portion 141 may both be made of metal. Optionally, an etching resistance of the connecting portion 143 is greater than an etching resistance of the support portion 141. For example, a material of the connecting portion 143 includes molybdenum, and a material of the support portion 141 includes aluminum.

In some other possible implementations, only the connecting portion 143 may be electrically conductive. For example, the material of the connecting portion 143 includes a conductive metal material, and the material of the support portion 141 includes an inorganic material or an organic material.

In some possible implementations, an orthographic projection of a side of the support portion 141 away from the substrate 111 on the substrate 111 is located within an orthographic projection of a side of the support portion 141 close to the substrate 111 on the substrate 111. Optionally, a thickness of the connecting portion 143 is less than a thickness of the support portion 141 in the direction away from the substrate 111. That is, in a cross section perpendicular to the substrate 111, the cross-sectional shape of the support portion 114 is a trapezoid that is smaller on the side away from the substrate 111 and larger on the side close to the substrate 111.

In this way, the shape of the support portion 141 that is smaller on the side away from the substrate 111 and larger on the side close to the substrate 111 can reduce the impact on the evaporation gas flow during evaporation of the encapsulation material layer, making the encapsulation material layer formed by evaporation more uniform in thickness.

In this case, an orthographic projection of the first portion 171 of the encapsulation unit 170 on the substrate 111 may not overlap with an orthographic projection of the third portion 173 on the substrate 111.

In some other possible implementations, the orthographic projection of the side of the support portion 141 close to the substrate 111 on the substrate 111 is located within the orthographic projection of the side of the support portion 141 away from the substrate 111 on the substrate 111, and the thickness of the connecting portion 143 is less than the thickness of the support portion 114 in the direction away from the substrate 111. The thickness of the connecting portion 143 is less than the thickness of the support portion 141 in the direction away from the substrate 111. That is, in a cross section perpendicular to the substrate 111, the cross-sectional shape of the support portion 114 is an inverted trapezoid that is smaller on the side close to the substrate 111 and larger on the side away from the substrate 111.

In some other possible implementations, the orthographic projection of the side of the support portion 141 close to the substrate 111 on the substrate 111 is located within the orthographic projection of the side of the support portion 141 away from the substrate 111 on the substrate 111. In addition, the orthographic projection of the side of the connecting portion 143 away from the substrate 111 on the substrate 111 is located within the orthographic projection of the side of the connecting portion 143 close to the substrate 111 on the substrate 111.

That is, in a cross section perpendicular to the substrate 111, the cross-sectional shape of the support portion 114 is an inverted trapezoid that is smaller on the side close to the substrate 111 and larger on the side away from the substrate 111, and the cross-sectional shape of the connecting portion 143 is a trapezoid that is smaller on the side away from the substrate 111 and larger on the side close to the substrate 111.

Optionally, a ratio of a thickness of the support portion 114 to a thickness of the connecting portion 143 ranges from 2:3 to 3:2 in the direction away from the substrate 111.

That is, in a cross section perpendicular to the substrate 111, the cross-sectional shaped formed by the connecting portion 143 and the support portion 141 is an hourglass shape.

In some other possible implementations, a side surface of the support portion 141 facing the isolation opening includes a recess that is recessed in a direction away from the isolation opening. Optionally, a thickness of the connecting portion 143 is less than a thickness of the support portion 141 in the direction away from the substrate 111.

That is, in a cross section perpendicular to the substrate 111, the cross-sectional shape of the connecting portion 143 is an hourglass shape.

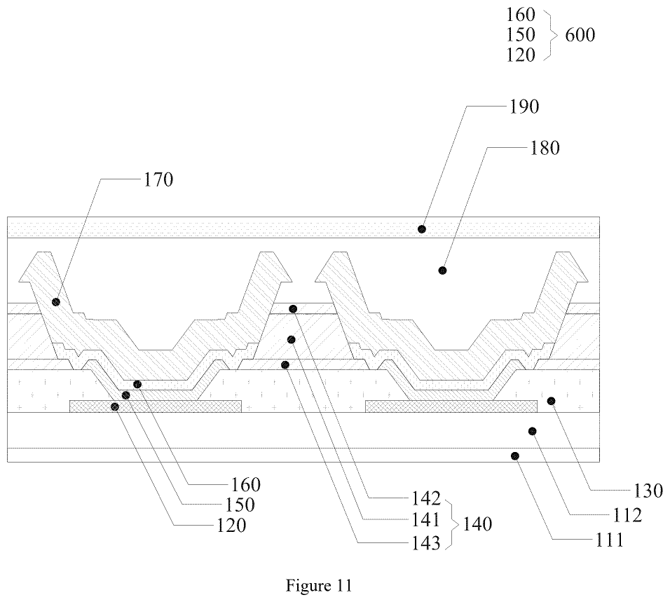

In some possible implementations, referring to FIG. 11, a plurality of encapsulation units 170 constitute a first encapsulation layer. The display panel according to an embodiment of the present application may further include a second encapsulation layer 180 and a third encapsulation layer 190 which are located on a side of the first encapsulation layer away from the substrate 111 and stacked in the direction away from the substrate 111.

Optionally, materials of the encapsulation unit 170 and the third encapsulation layer 190 each include an inorganic material, and a material of the second encapsulation layer 180 includes an organic material. For example, the encapsulation unit 170 and the third encapsulation layer 190 may be formed by means of chemical vapor deposition (CVD), and the second encapsulation layer 180 may be formed by means of ink-jet printing (IJP).

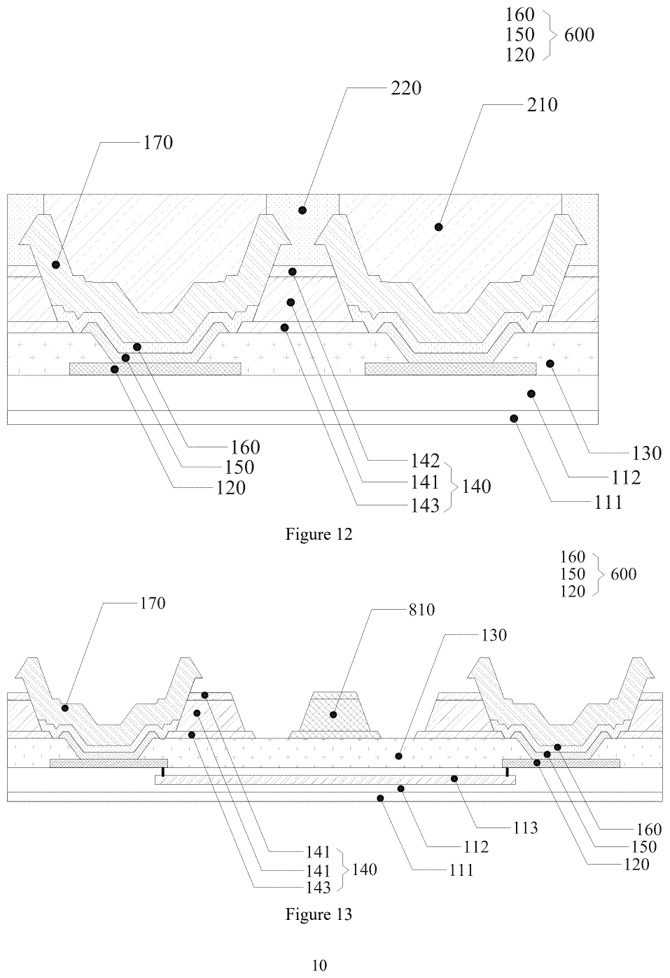

In some possible implementations, referring to FIG. 12, the display panel further includes a filter layer located on the side of the isolation structure 140 away from the substrate 111. The filter layer includes a plurality of filter units 210. An orthographic projection of each filter unit 210 on the substrate 111 at least partially overlaps with an orthographic projection of the corresponding light-emitting device 600 on the substrate 111, and the filter unit 210 has the same transmitting color as an emitting color of a corresponding one of the light-emitting devices 600. For example, a sub-pixel that has a red emitting color corresponds to a filter unit 210 that has a red transmitting color, a sub-pixel that has a green emitting color corresponds to a filter unit 210 that has a green transmitting color, and a sub-pixel that has a blue emitting color corresponds to a filter unit 210 that has a blue transmitting color.

Optionally, the filter layer further includes light shielding units 220 located between adjacent filter units 210, and an orthographic projection of each light shielding unit 220 on the substrate 111 at least partially overlaps with an orthographic projection of the isolation structure 140 on the substrate 111. The light shielding unit 220 may be made of an opaque material, thereby reducing the mixing of emitting colors of the light-emitting units 150.

In some possible implementations, referring to FIG. 13, a gap is provided between adjacent isolation structures 140, and the display panel further includes first touch traces 810 disposed in the same layer as the isolation structures 140. Each first touch trace 810 is located in a gap between adjacent isolation structures 140.

Specifically, according to an embodiment of the present application, while the isolation structures 140 are being formed by etching, the first touch traces 810 located between adjacent isolation structures 140 may be formed by etching.

Optionally, the plurality of first touch traces 810 may be staggered to form touch electrodes. The isolation structures 140 may be electrically connected via a trace layer located in the functional layer.

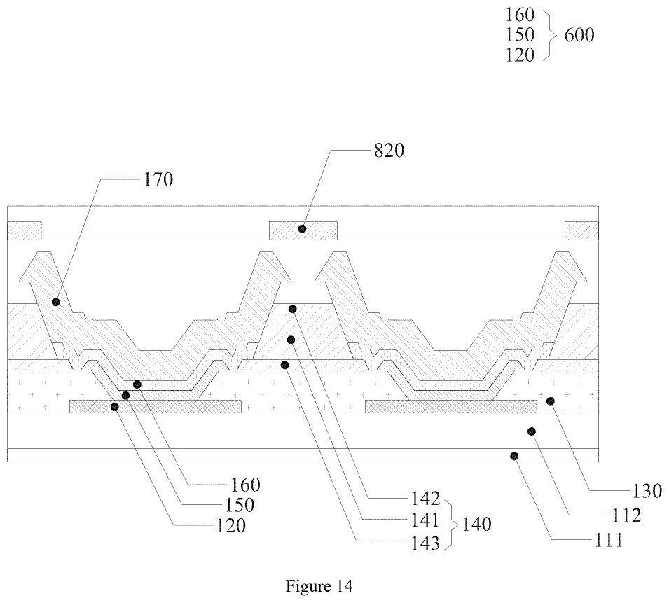

In other possible implementations, referring to FIG. 14, the display panel further includes a touch functional layer located on the side of the isolation structure 140 away from the substrate 111. The touch functional layer includes a plurality of second touch traces 820, and an orthographic projection of each second touch trace 820 on the substrate 111 at least partially overlaps with the orthographic projection of the isolation structure 140 on the substrate 111.

Optionally, the plurality of second touch traces 820 may be staggered to form touch electrodes.

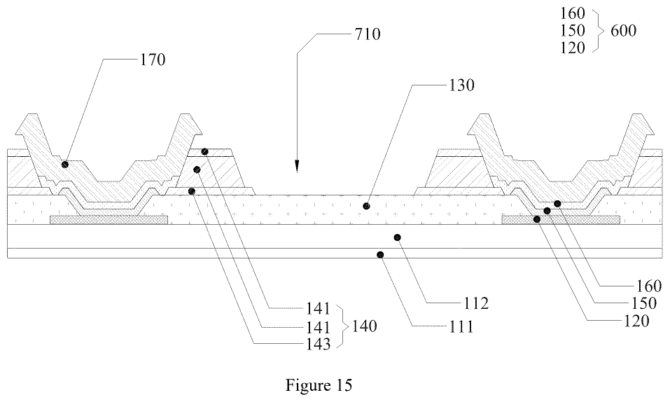

In some possible implementations, referring to FIG. 15, the isolation structure 140 further includes a light-transmitting opening 710, and the light-transmitting opening 710 is located between adjacent isolation openings. In this way, external light may be transmitted through the light-transmitting opening 710 to an optical device (e.g., a camera, a light intensity sensor, or an optical fingerprint sensor) under the display panel.

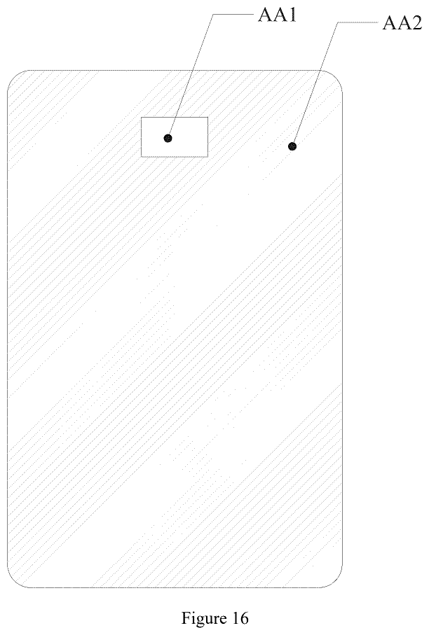

Optionally, referring to FIG. 16, the display panel includes a first active area AA1 and a second active area AA2 at least partially surrounding the first active area AA1, and the light-transmitting openings 710 are located in the first active area AA1.

Optionally, the display panel further includes a plurality of array functional layers 112 located between the substrate 111 and the isolation structures 140. Each array functional layer 112 includes a light-transmitting region, and an orthographic projection of the light-transmitting region on the substrate 111 at least partially overlaps with the orthographic projection of the light-transmitting opening 710 on the substrate 111.

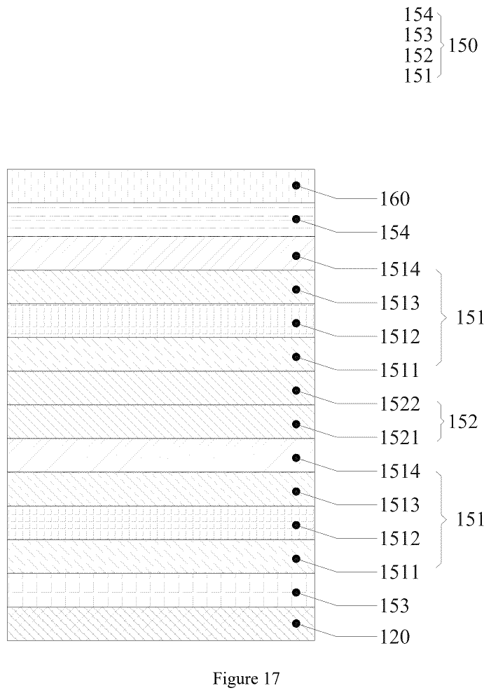

In some possible implementations, referring to FIG. 17, the light-emitting unit 150 may include at least two light-emitting functional layers 151 which are stacked in the direction away from the substrate 111 and which have a same emitting color, and the light-emitting unit 150 further includes a charge generation layer 152 located between adjacent light-emitting functional layers.

Optionally, each light-emitting functional layer 151 includes a hole transport layer 1511, an electroluminescent layer 1512, a hole blocking layer 1513 and an electron transport layer 1514 which are stacked in the direction away from the substrate 111.

Optionally, the light-emitting unit 151 further includes a hole injection layer 153 located between the light-emitting functional layer 151 closest to the substrate 111 and the first electrode 120. And/or the light-emitting unit 151 further includes an electron injection layer 154 located between the light-emitting functional layer 151 farthest from the substrate 111 and the second electrode 150.

Optionally, the charge generation layer 152 includes a first charge generation layer 1521 and a second charge generation layer 1522 which are stacked in the direction away from the substrate 111. The first charge generation layer 1521 includes an N-type dopant material, and the second charge generation layer 1522 includes a P-type dopant material.

A display panel is provided according to an embodiment of the present application, as shown in FIG. 8. The display panel may be manufactured by the method for manufacturing a display panel according to an embodiment of the present application. The display panel may include a substrate 111, isolation structures 140, and light-emitting devices 600.

The isolation structures 140 are located on one side of the substrate 111, and the isolation structures 140 enclose isolation openings. Each isolation structure 140 includes a support portion 141 and a shielding portion 142 located on a side of the support portion away from the substrate 111. At least part of a side of the isolation structure 140 close to the substrate 111 is electrically conductive.

Each light-emitting device 600 is at least partially located within the corresponding isolation opening.

An encapsulation unit 170 is located on a side of the light-emitting device 600 away from the substrate 111. The encapsulation unit 170 includes a first portion 171 located within the isolation opening, a second portion 172 located on the side wall of the isolation structure 140 facing the isolation opening, and a third portion 173 located on a side of the isolation structure 140 away from the substrate 111. The second portion 172 connects the first portion 171 and the third portion 173. The second portion 172 forms a continuous slope 1721 relative to the substrate 111, and a gap is provided between the third portion 173 and a side of the shielding portion 142 away from the substrate 111. An orthographic projection of a top portion of the second portion 172 (i.e., a top portion of the slope 1721) on the substrate 111 is located on a side, away from the isolation opening, of the orthographic projection of a bottom portion of the second portion 172 (i.e., a bottom portion of the slope 1721) on the substrate 111.

According to an embodiment of the present application, since the part of the shielding portion 142 at the top portion of the isolation structure 140 is shortened, the overall shape of the isolation structure 140 is smaller at the side away from the substrate 111 and larger at the side close to the substrate 111. That is, a side surface of the isolation structure 140 facing the isolation opening forms the slope 1721, and accordingly, the encapsulation unit 170 adhered to the side surface of the isolation structure 140 facing the isolation opening also forms the slope 1721. In this way, the encapsulation units 170 are more uniform in thickness.

The present application further provides an electronic device including a display panel according to the present application or including a display panel manufactured by the method for manufacturing a display panel according to an embodiment of the present application. The electronic device may include a mobile phone, a tablet computer, a smart wearable device, a television, a laptop computer, a monitor, and other devices with a display function.

In summary, according to a display panel, a method for manufacturing a display panel, and an electronic device provided in the present application, in a display panel having isolation structures, the shielding portion at the top end of each isolation structure is shortened before providing the encapsulation material layer, which can thus reduce the impact of the shielding portion on evaporation gas flow during formation of the encapsulation material layer by evaporation, so as to ensure the structural stability of the subsequently formed encapsulation units, thereby improving the encapsulation effectiveness.

The technical features of the above embodiments may be randomly combined. To make the description concise, not all possible combinations of the technical features in the above embodiments are described. However, the combinations of these technical features shall be considered as falling within the scope recorded in this specification provided that no conflict exists.

The above embodiments merely represent several implementations of the present application, giving specifics and details thereof, but should not be understood as limiting the scope of the present application thereby. It should be noted that various variations and improvements may also be made by those of ordinary skill in the art without departing from the spirit of the present application and shall fall within the scope of protection of the present application. Therefore, the scope of protection of the present application shall be in accordance with the appended claims.

1. A display panel, comprising:
a substrate;
at least one isolation structure located on one side of the substrate, the at least one isolation structure enclosing a plurality of isolation openings, and each of at least one the isolation structure comprising a support portion and a shielding portion located on a side of the support portion away from the substrate, an orthographic projection of the shielding portion on the substrate being located within an orthographic projection of the support portion on the substrate, and at least part of a side of the isolation structure close to the substrate being electrically conductive; and
a plurality of light-emitting devices disposed in one-to-one correspondence with the plurality of isolation openings, any of the light-emitting devices being at least partially located within a corresponding isolation opening, and each of the light-emitting devices comprising a first electrode, a light-emitting unit and a second electrode which are stacked in a direction away from the substrate, the second electrode being electrically connected to the isolation structure.

2. The display panel according to claim 1, wherein the orthographic projection of the shielding portion on the substrate is located within an orthographic projection of the side of the support portion away from the substrate on the substrate;
the orthographic projection of the shielding portion on the substrate coincides with the orthographic projection of the side of the support portion away from the substrate on the substrate;
or a thickness of the shielding portion is less than a thickness of the support portion in the direction away from the substrate.

3. The display panel according to claim 1, further comprising a plurality of encapsulation units each located on a side of each of the plurality of light-emitting devices away from the substrate, wherein the plurality of encapsulation units are disposed in one-to-one correspondence with the plurality of isolation openings, and any of the encapsulation units at least partially extends from an interior of a corresponding one of the isolation openings, along a side wall of the isolation structure facing the isolation opening, to a side of the isolation structure away from the substrate.

4. The display panel according to claim 3, wherein any of the encapsulation units comprises a first portion located within the isolation opening, a second portion located on the side wall of the isolation structure facing the isolation opening, and a third portion located on a side of the isolation structure away from the substrate, wherein the second portion connects the first portion and the third portion;
a gap is provided between the third portion and the side of the shielding portion away from the substrate; and
an average film thickness of the first portion is greater than or equal to an average film thickness of the second portion.

5. The display panel according to claim 3, wherein the encapsulation units corresponding to at least
part of the light-emitting units that have a same emitting color and that are adjacent to each other are connected to each other on the side of the isolation structure away from the substrate.

6. The display panel according to claim 1, wherein each of the at least one isolation structure comprises a connecting portion and a support portion located on a side of the connecting portion away from the substrate, wherein the connecting portion is electrically conductive, and the second electrode is electrically connected to the connecting portion; and
an orthographic projection of a side of the support portion close to the substrate on the substrate is located within an orthographic projection of the connecting portion on the substrate.

7. The display panel according to claim 6, wherein the orthographic projection of the side of the support portion away from the substrate on the substrate is located within the orthographic projection of the side of the support portion close to the substrate on the substrate; and
a thickness of the connecting portion is less than a thickness of the support portion in the direction away from the substrate.

8. The display panel according to claim 6, wherein the orthographic projection of the side of the support portion close to the substrate on the substrate is located within the orthographic projection of the side of the support portion away from the substrate on the substrate; and
a thickness of the connecting portion is less than a thickness of the support portion in the direction away from the substrate.

9. The display panel according to claim 6, wherein the orthographic projection of the side of the support portion close to the substrate on the substrate is located within the orthographic projection of the side of the support portion away from the substrate on the substrate;
an orthographic projection of the side of the connecting portion away from the substrate on the substrate is located within an orthographic projection of a side of the connecting portion close to the substrate on the substrate; and
a ratio of a thickness of the support portion to a thickness of the connecting portion ranges from 2:3 to 3:2 in the direction away from the substrate.

10. The display panel according to claim 6, wherein a side surface of the support portion facing the isolation opening comprises a recess that is recessed in a direction away from the isolation opening.

11. The display panel according to claim 3, further comprising a second encapsulation layer and a third encapsulation layer which are located on a side of each of the encapsulation units away from the substrate and are stacked in the direction away from the substrate; wherein
a material of each of the encapsulation unit and the third encapsulation layer comprises an inorganic material; and a material of the second encapsulation layer comprises an organic material.

12. The display panel according to claim 1, further comprising a filter layer located on the side of the at least one isolation structure away from the substrate, wherein the filter layer comprises a plurality of filter units, an orthographic projection of each of the filter units on the substrate at least partially overlapping with an orthographic projection of the light-emitting device on the substrate, and each of the filter units having a same transmitting color as an emitting color of a corresponding one of the light-emitting devices; and
the filter layer further comprises light shielding units located between adjacent filter units, an orthographic projection of each of the light shielding units on the substrate at least partially overlapping with an orthographic projection of the isolation structure on the substrate.

13. The display panel according to claim 1, wherein a gap is provided between adjacent isolation structures, and the display panel further comprises a first touch traces disposed in the same layer as the isolation structures and each located in the gap between adjacent isolation structures;
or the display panel further comprises a touch functional layer located on the sides of the isolation structures away from the substrate, the touch functional layer comprising a plurality of second touch traces, an orthographic projection of each of the second touch traces on the substrate at least partially overlapping with an orthographic projection of the isolation structure on the substrate.

14. (canceled)

15. The display panel according to claim 1, wherein each of the light-emitting units comprises at least two light-emitting functional layers which stacked in the direction away from the substrate and which have a same emitting color, and the light-emitting unit further comprises a charge generation layer located between adjacent light-emitting functional layers.

16. (canceled)

17. A method for manufacturing a display panel, the method comprising:
providing a substrate;
forming at least one isolation structure on one side of the substrate, wherein the at least one isolation structure encloses isolation openings, and each of the at least one isolation structure comprises a support portion and a shielding portion located on a side of the support portion away from the substrate, an orthographic projection of the support portion on the substrate being located within an orthographic projection of the shielding portion on the substrate; and the isolation openings comprise a first isolation opening and a second isolation opening;
sequentially providing a first light-emitting material layer and a first conductive material layer which are disposed in a full-coverage manner on a side of the at least one isolation structure away from the substrate;
removing a portion of a part of the shielding portion close to the first isolation opening, so that an orthographic projection of the part of the shielding portion close to the first isolation opening on the substrate is located within an orthographic projection of the support portion on the substrate;
providing a first encapsulation material layer which is disposed in a full-coverage manner on a side of the first conductive material layer away from the substrate; and
etching the first encapsulation material layer, the first conductive material layer and the first light-emitting material layer to form an encapsulation unit, a second electrode and a light-emitting unit which are at least partially located in the first isolation opening.

18. The method according to claim 17, wherein after the step of etching the first encapsulation material layer, the first conductive material layer and the first light-emitting material layer, the method further comprises:
sequentially providing a second light-emitting material layer and a second conductive material layer which are disposed in a full-coverage manner on a side of the isolation structure away from the substrate;
removing a portion of a part of the shielding portion close to the second isolation opening, so that an orthographic projection of the part of the shielding portion close to the second isolation opening on the substrate is located within an orthographic projection of the support portion on the substrate;
providing a second encapsulation material layer which is disposed in a full-coverage manner on a side of the second conductive material layer away from the substrate; and
etching the second encapsulation material layer, the second conductive material layer and the second light-emitting material layer to form an encapsulation unit, a second electrode and a light-emitting unit which are at least partially located in the second isolation opening.

19. The method according to claim 17, wherein the step of removing a portion of a part of the shielding portion close to the first isolation opening comprises:
removing a portion of a part of the shielding portion close to the first isolation opening by means of laser etching.

20. An electronic device, comprising a display panel according to claim 1, or a display panel manufactured by the method for manufacturing a display panel according to claim 17.

21. The display panel according to claim 1, wherein each of the at least one isolation structure comprises a connecting portion and a support portion located on a side of the connecting portion away from the substrate, wherein the support portion is electrically conductive, and the second electrode is electrically connected to the support portion; and
an etching resistance of the connecting portion is greater than an etching resistance of the support portion, a material of the connecting portion comprises metal, and a material of the support portion comprises at least one of metal, an inorganic material, and an organic material.

22. The display panel according to claim 15, wherein the light-emitting functional layer comprises a hole transport layer, a light-emitting material layer, a hole blocking layer and an electron transport layer which are stacked in the direction away from the substrate;
the light-emitting unit further comprises a hole injection layer located between the light-emitting functional layer closest to the substrate and the first electrode, or an electron injection layer located between the light-emitting functional layer farthest from the substrate and the second electrode; and
the charge generation layer comprises a first charge generation layer and a second charge generation layer which are stacked in the direction away from the substrate, the first charge generation layer comprising an N-type dopant material, and the second charge generation layer comprising a P-type dopant material.
